(19) United States
(12) Patent Application Publication
(10) Pub. No.: US 2008/0054986 A1
(43) Pub. Date: Mar. 6, 2008

(54) Resonant-Current-Source Gate Drive for Simultaneous Operation of Thyristors Using Alternating-Current in the Resonant Circuit

(76) Inventor: Lee E. Berkebile, West Mifflin, PA (US)

Correspondence Address: OCCHIUTI ROHLICEK & TSAO, LLP, 10 FAWCETT STREET, CAMBRIDGE, MA, 02138, US

(21) Appl. No.: 11/842,764

(22) Filed: Aug. 21, 2007

Related U.S. Application Data
(63) Continuation-in-part of application No. 11/405,184, filed on Apr. 17, 2006, now abandoned.

(51) Int. Cl. H03K 17/725

(52) U.S. Cl. 327/447

(57) ABSTRACT

Systems, circuits, and methods for providing alternate polarity current pulses through a current transformer for operation of a thyristor are disclosed.

### CROSS-REFERENCE TO RELATED APPLICATIONS

This application is a continuation-in-part of U.S. application Ser. No. 11/405,184, filed Apr. 17, 2006, and titled “Resonant-Current-Source Gate Drive for Simultaneous Operation of Thyristors Using Alternating-Current in the Resonant Circuit,” which is incorporated in its entirety by reference.

### BACKGROUND

Electronic circuits are typically used to provide gate pulse signals that turn on thyristors used for electrical switching. When the thyristors are used at high voltage, electrically isolating the electronic gate drive circuits from the high voltage is required. Common isolation methods include optical fibers as well as voltage and current transformers.

Typical gate drives use two separate circuits to provide gate pulses to the thyristors. When transformers are used to couple the gate drivers, the magnetic material in the transformers is not utilized efficiently due to the direct-current (DC) component in the gate drive pulses. The DC component causes residual magnetism to build up in the magnetic cores of the transformer. As a result, output pulses from the transformers are degraded as the number of pulses increases. Thus, later pulses may not efficiently switch the thyristors on. In this circumstance, much higher input current is required to provide adequate output pulses.

Thyristors are turned on by electrical current signals (other types of electrical devices may be turned on by voltage signals). Typically, current source gate drives are used to turn on thyristors. When thyristors are used at high voltage, current transformers are typically used to electrically isolate the electronic gate drive circuits from the high voltage. A typical gate drive uses two circuits that provide alternating pulses (loop 1 and loop 2 in FIG. 1). Each loop is coupled to a separate current transformer. The pulses are usually generated using resonant circuits. The positive portion of each pulse provides the current signal switch the thyristor on. The smaller negative loop recharges the resonant circuit to increase the efficiency of the gate drive. Because the positive pulse is larger than the negative pulse, there is a positive direct-current component in the gate drive signal. This mode of operation is described in greater detail in U.S. Pat. No. 5,585,758, which is incorporated in its entirety by reference.

FIG. 1 shows the input currents 10 and 12 on the primary side of the current-transformers for two typical gate drive circuits, designated as loop 1 and loop 2. These two loop circuits use separate current transformers. The output of the current transformers is rectified and combined to provide the thyristor gate current i(GATE) 14. The input currents 10 and 12 maintain approximately the same magnitude as a function of time, but the gate current i(GATE) 14 degrades as a function of time. The gate current 14 decreases over time as residual magnetism builds up in the current transformer core (typically ferrite of other magnetic material) due to the direct-current component of the gate drive signal.

FIG. 2 shows a typical B-H curve of a magnetic material. A change in a signal on the horizontal axis (B) provides an output on the vertical axis (H). The output of the B-H curve for a magnetic material is not linear. For example, as shown in FIG. 2, an input X1 gives an output Y1 (as indicated by line 22). If the input is doubled (X2) the output (Y2) is not doubled but rather increases only a small amount. As shown in FIG. 1 above, if there is a direct-current component in the input signal (e.g., gate pulses), the first input starts at zero, but the output decreases over time due to the residual magnetism. A positive input results in a shift in the B value to the right of the vertical axis (as indicated by line 24). Negative input pulses result in a shift in the B value to the left of the vertical axis (as indicated by line 20). An alternating-current (AC) drive has both positive and negative pulses. An input the same magnitude as X1 but symmetrical to the vertical axis (X1′) gives a larger change in H (Y1′) then when the input is not symmetrical (Y1).

FIG. 3 shows a typical current-transformer coupled gate drive circuit 30. Two gate drive loops 32 and 34 pass through several current-transformers 42, 43, 44, 45, 46, and 47 with one pair of current transformers being provided for each thyristor 36, 38, and 40. The output of the current transformers is connected such that each pair of current-transformers operates one thyristor 36, 38, and 40. For example, transformers 42 and 43 are connected to thyristor 36. The gate drive circuit 30 includes series diodes DS connected between a terminal of the transformer and the thyristor. The series diodes DS prevent application of a negative voltage across the thyristor gates. The gate drive circuit 30 also includes diodes DB that provide a return path for the negative loop of the gate drive signal.

FIG. 4 shows a typical resonant gate drive circuit 50. The gate drive circuit uses two circuits. Each circuit includes a capacitor C that is alternately charged through the RECHARGE circuit 52 and then discharged through the gate loop circuits 62 and FIRE circuit 60 to produce the gate signals. The RECHARGE and FIRE circuits 56 and 60 can be transistors that are turned on and off by electronic control timing circuits 54 and 58. The return of the gate loop circuit 62 (the top of the FIRE circuit 60) is connected to the power supply 52 to limit the voltages on the transistor used in the FIRE circuit 60.

FIGS. 5A and 5B show circuit diagrams of a push-pull current circuit 70 and a push-pull voltage circuit 80, respectively. The push-pull current circuit 70 and push-pull voltage circuit 80 generate substantially continuous gate drive signals (as shown by signals 71 and 81). Gate drives such as the push-pull current circuit 70 and a push-pull voltage circuit 80 generate a square wave inputs having fast rise times. In circuits 70 and 80, isolation transformers 72, 74, 82, and 84 are disposed in a current path between the low voltage drive circuits and the thyristors. In order to maintain the fast rise times, the isolation transformers 72, 74, 82, and 84 must be very efficient and have a low impedance value. In some implementations, voltage source continuous gate drives use higher impedance isolation transformers and often incorporate a fast front circuit at the high voltage level.

### SUMMARY

This disclosure relates to the simultaneous operation of thyristors using a thyristor gate drive. More specifically, this disclosure relates to gate drives that include an alternating-current gate drive that increases the efficiency of the gate drive circuitry.

In some aspects, a resonant gate drive circuit includes an isolation transformer comprising a first primary winding; a second primary winding, and a secondary winding. The resonant gate drive circuit also includes a first resonant circuit coupled to the first primary winding. The first primary winding is disposed in a first polarity relative to the secondary winding. The resonant gate drive circuit also includes a second resonant circuit coupled to the second primary winding. The second primary winding is disposed in a second polarity relative to the secondary winding. The second polarity is opposite of the first polarity. The resonant gate drive circuit also includes a rectifier circuit electrically connected to the isolation transformer.

Embodiments can include one or more of the following.

The first resonant circuit can be configured to generate a positive signal on the secondary winding of the isolation transformer. The second resonant circuit can be configured to generate a negative signal on the secondary winding of the isolation transformer. The rectifier circuit can be configured to rectify the positive and negative signals. The resonant gate drive circuit can be configured to provide a substantially continuous gate drive signal to a thyristor.

The resonant gate drive circuit can also include a capacitor electrically connected to an output of the rectifier circuit. The resonant gate drive circuit can also include a thyristor electrically connected to the capacitor. The resonant gate drive circuit can also include a resistor disposed in a current path between the capacitor and the thyristor.

In some aspects, a method for generating a gate drive signal can include receiving at an isolation transformer, alternate-polarity current pulses provided by a first resonant circuit and a second resonant circuit coupled to the isolation transformer in opposite polarities. The method can also include rectifying a signal generated by the isolation transformer and applying the rectified signal to a thyristor.

Embodiments can include one or more of the following.

The alternate-polarity current pulses can include a first current pulse having a positive current value and a second current pulse having a negative current value. The isolation transformer can include a first primary winding; a second primary winding, and a secondary winding. The first resonant circuit can be coupled to the first primary winding and be disposed in a first polarity relative to the secondary winding. The second resonant circuit can be coupled to the second primary winding and be disposed in a second polarity relative to the secondary winding where the second polarity is opposite of the first polarity. Receiving at the isolation transformer, alternate-polarity current pulses provided by the first resonant circuit and the second resonant circuit can include receiving at the secondary winding a positive current from the first primary winding and receiving at the secondary winding a negative current from the second primary winding.

In some aspects, a circuit can include a first resonant circuit, a second resonant circuit, and a current transformer. The first resonant circuit and the second resonant circuit can be configured to provide alternate polarity current pulses through the current transformer for operation of a thyristor.

Embodiments can include one or more of the following.

The circuit can include a rectifier circuit configured to rectify the signal from the transformer. The circuit can be configured to separate a positive thyristor current pulse and a negative recharge current pulse.

In some aspects, a system includes a current transformer and one or more circuits to provide alternate polarity current pulses through the current transformer for operation of a thyristor.

Embodiments can include one or more of the following.

The system can also include a rectifier circuit configured to rectify the signal from the transformer. The circuit can be configured to separate a positive thyristor current pulse and a negative recharge current pulse. The system can also include a diode electrically connected to the circuit, the diode being configured to provide a negative return loop for the circuit. The one or more circuits can include a first resonant circuit and a second resonant circuit. The transformer can include a first primary winding; a second primary winding and a secondary winding. The first resonant circuit can be coupled to the first primary winding in a first polarity relative to the secondary winding. The second resonant circuit can be coupled to the second primary winding in a second polarity relative to the secondary winding where the second polarity being opposite of the first polarity.

In some embodiments, the gate drive circuit generates a substantially continuous thyristor gate drive signal and prevents thyristor turn off when high harmonic currents are present.

In some embodiments, the resonant circuit gate drive provides a continuous gate drive signal by separating the positive thyristor current pulse and the negative recharge current pulse in the low voltage circuits. Separating the positive thyristor current pulse and the negative recharge current pulse reduces the number of isolation transformers. Such a gate drive allows a single isolation transformer to be included in the circuit for each pair of gate drive circuits and enables using a signal-conditioning circuit at high voltage to provide a continuous gate drive signal to the thyristor.

Other features and advantages of the invention are apparent from the following description, and from the claims.

### DESCRIPTION OF DRAWINGS

FIG. 1 shows a “picket fence” gate drive utilizing a number of pulses to provide thyristor gate signal.

FIG. 2 shows operating characteristics of the magnetic material used in transformers.

FIG. 3 shows a current-transformer coupled gate drive circuit.

FIG. 4 shows a resonant gate drive circuit.

FIG. 5A shows a resonant gate drive circuit.

FIG. 5B shows a resonant gate drive circuit.

FIG. 6 shows an alternating-current “picket-fence” gate drive.

FIG. 7 shows an alternating-current current-transformer coupled gate drive circuit.

FIG. 8 shows a “recharge” energy saving feature of the resonant gate drive.

FIG. 9 shows an improved alternating-current gate drive circuit.

FIG. 10 shows a resonant gate drive circuit.

### DETAILED DESCRIPTION

Current-source gate-drives are commonly used for simultaneous operation of series of parallel thyristors. Resonant circuits are typically used to provide a high-efficiency gate-current source. The gate-current source is coupled to the thyristors with transformers that include magnetic cores. Resonant circuits often use current pulses of one polarity (e.g., direct-current pulses) resulting in residual magnetism in the magnetic cores of the transformers, thus reducing the efficiency of the gate-drive circuit, and requiring increased input energy to provide reliable thyristor operation.

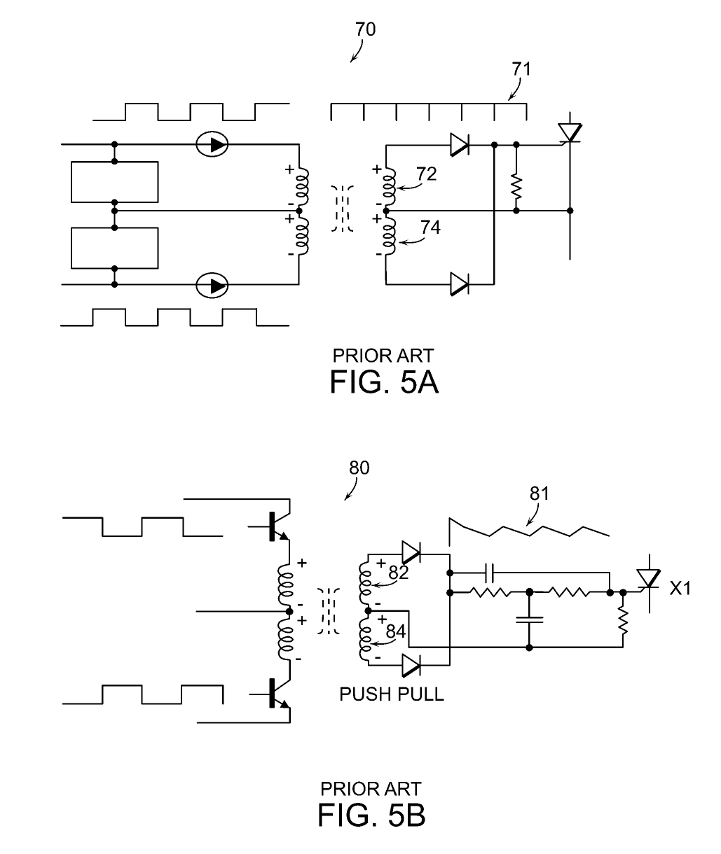

This disclosure relates to the simultaneous operation of thyristors using an improved thyristor gate drive circuit. More specifically, this disclosure describes gate drive circuits featuring an alternating-current (AC) gate drive circuit that increases the efficiency of the gate drive circuitry. This disclosure also describes a current-transformer doubled thyristor gate drive. The circuit-transformer provides increased efficiency for a given size and material used in the current transformer core, or permits the use of smaller, lower cost cores while maintaining the same efficiency. The circuit-transformer also uses one-half as many current transformers as conventional thyristor gate drives (e.g., gate drives such as those shown in FIGS. 5A and 5B above).

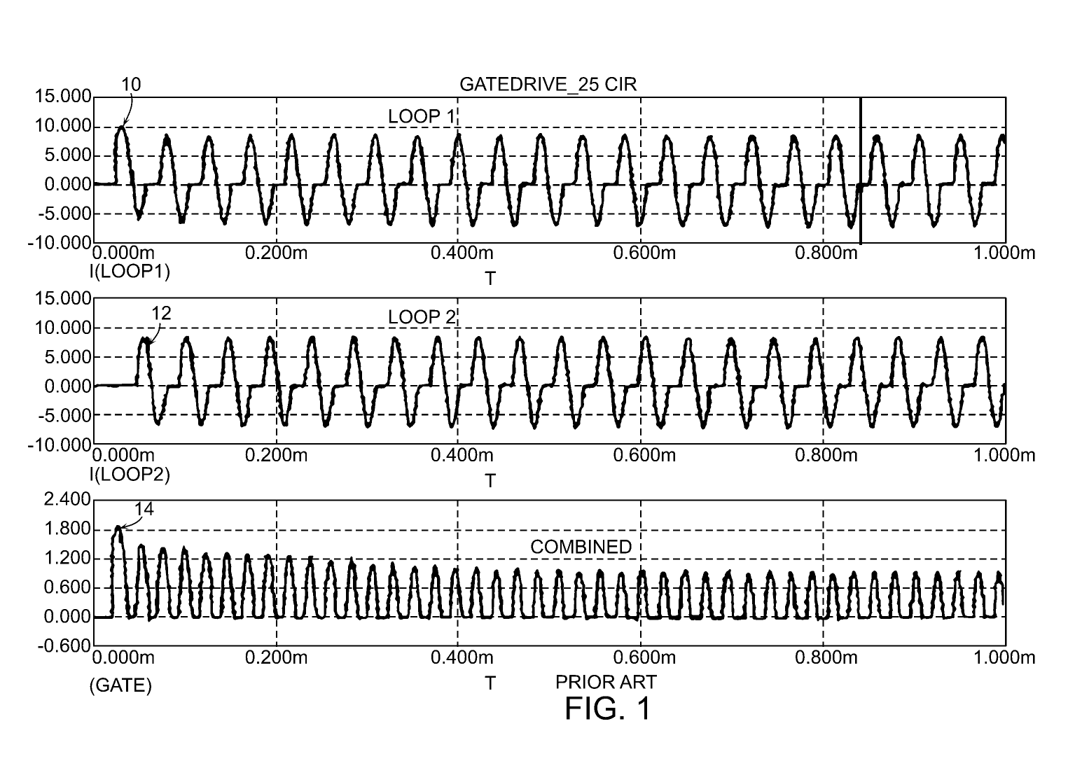

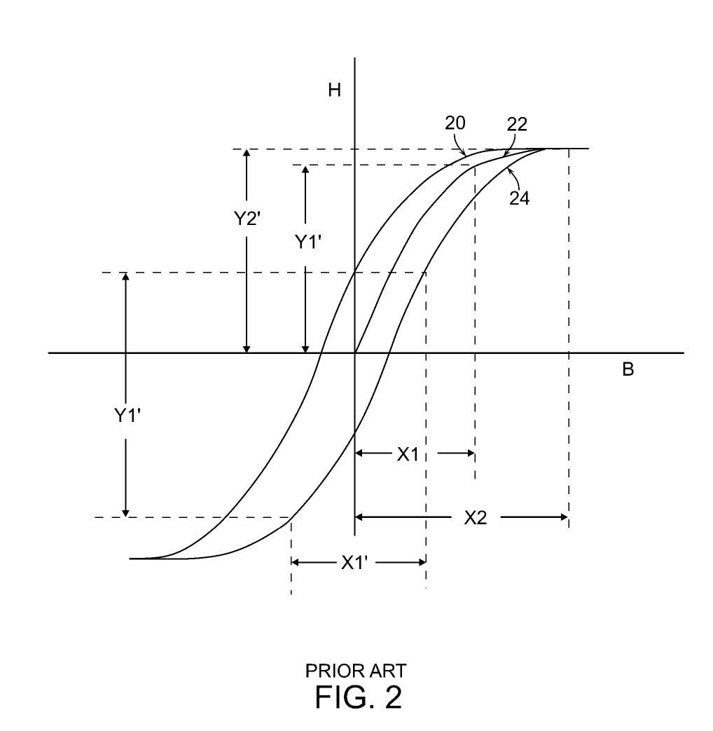

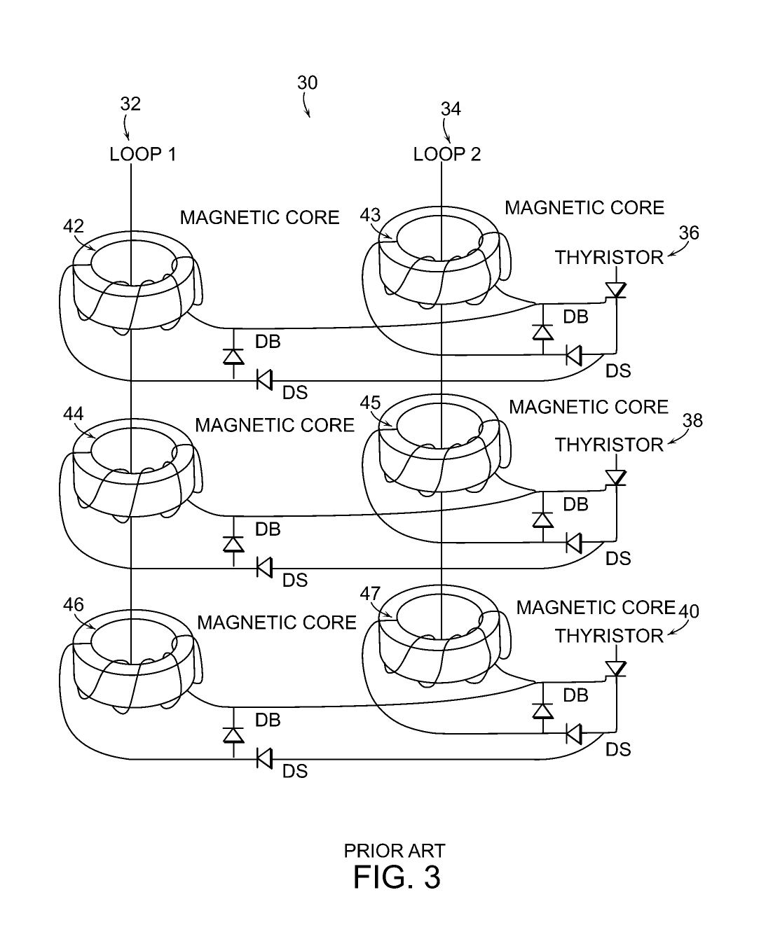

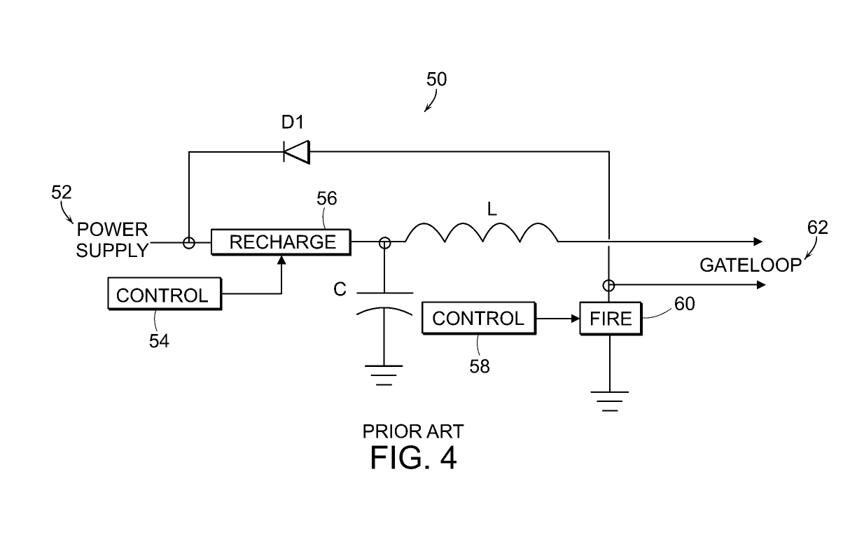

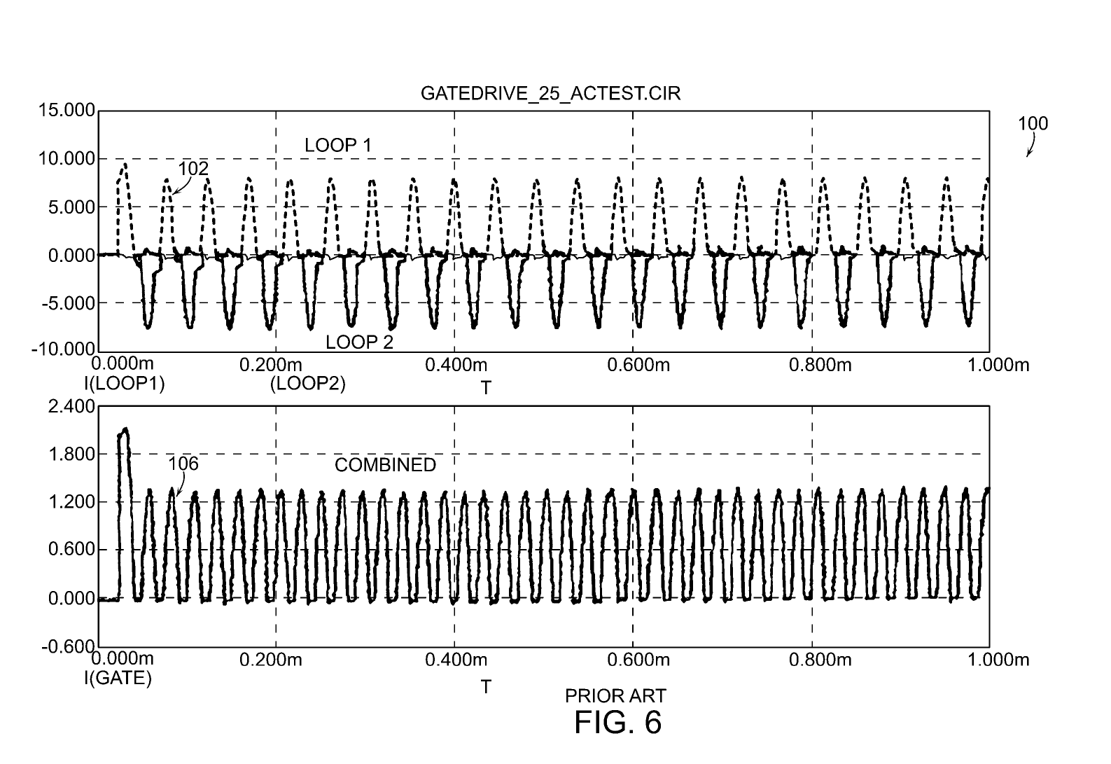

FIG. 6 shows input and output signals from an alternating-current gate drive. The two gate pulse circuits generate input signals having opposite polarities. The input signals are applied to the transformer in opposite directions producing alternating current as indicated by line 102. This alternating current 102 magnetizes the core alternatively in each direction (e.g., in the positive and negative directions) so that there is substantially no magnetic build up in the core of the transformer resulting in an increased efficiency of the gate drive. The magnitude of the input current loop (loop 1) for producing the gate current 106 i(GATE) can be less than in the conventional circuit (FIG. 1). Additionally, in the alternating-current gate drive the gate current 106 remains substantially constant (e.g., does not decrease in the magnitude over time) because there is substantially no residual magnetism in the magnetic core of the transformer. In some embodiments, the first pulse is slightly lower than the second pulse because the first pulse starts at zero on the B-H curve of the magnetic material, while the second pulse is in the opposite direction and thus more symmetrical to the vertical axis (see FIG. 2 above).

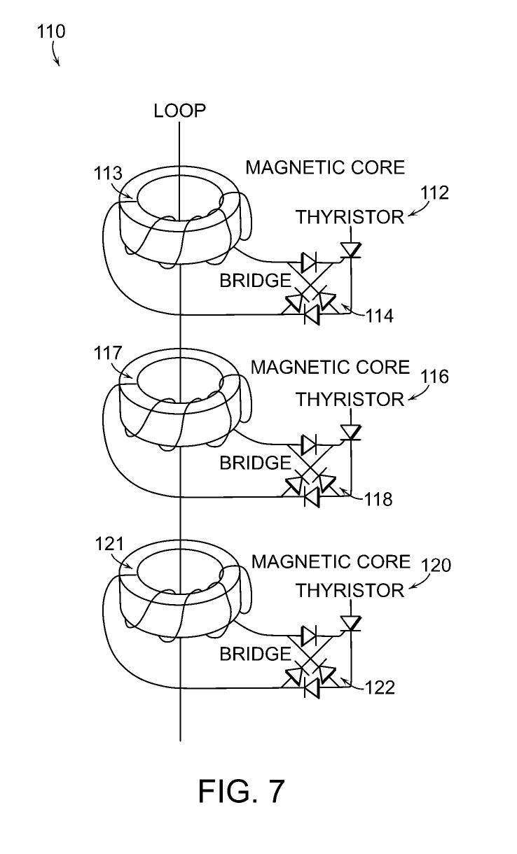

FIG. 7 shows an alternating-current (AC) current-transformer coupled gate drive circuit 110 of this disclosure. The AC) current-transformer coupled gate drive circuit 110 includes a set of current-transformers 113, 117, and 121. The outputs of the current-transformers 113, 117, and 121 are rectified using bridge rectifiers (e.g., bridge rectifiers 114, 118, and 122) to provide only positive pulses to the thyristor gates (e.g., thyristors 112, 116, and 120).

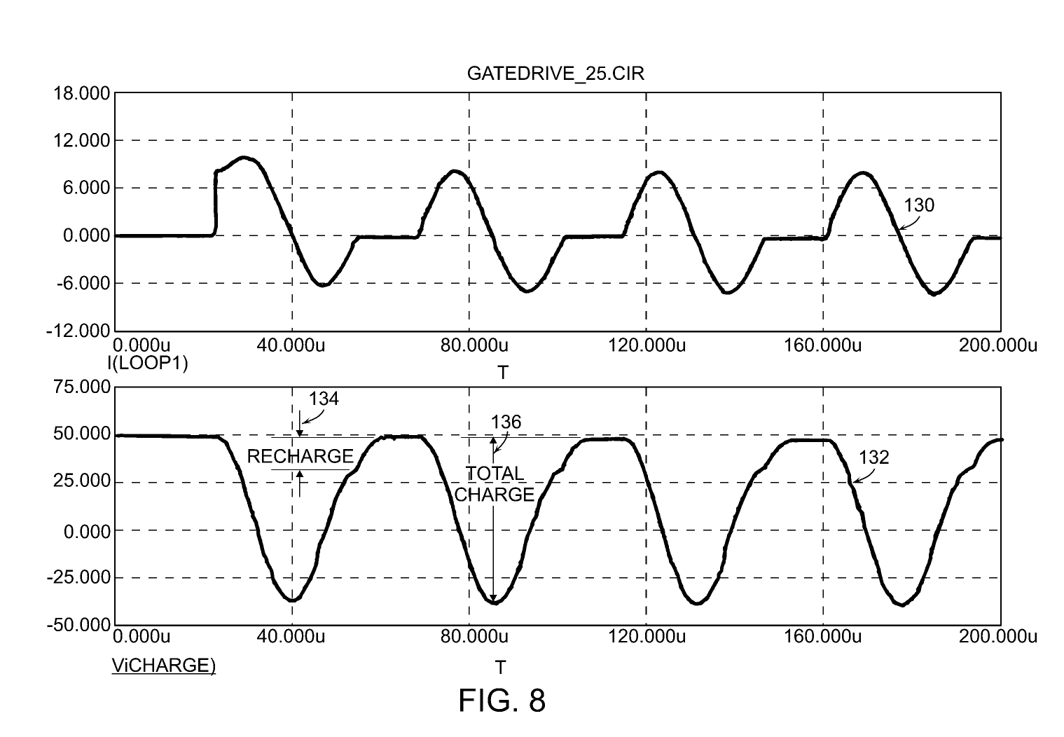

FIG. 8 shows the operation of the AC current-transformer coupled gate drive circuit 110. The output 130 of the gate drive circuit is a damped sine wave with the positive pulse larger than the negative pulse. The output signal 130 is generated by discharging a positively charge capacitor through an inductor. FIG. 8 also shows the capacitor voltage 132 (CHARGE). The voltage starts at a positive level, and then becomes negative as the pulse is formed. If the negative loop were not present, the capacitor would remain at this negative value and would use considerable energy for recharging to the net pulse (TOTAL ENERGY 136). The negative loop restores some of the energy to the capacitor so a smaller amount of energy is used to recharge the capacitor (RECHARGE 134). The amount of energy used to recharge the capacitor is approximately ¼^{th} of the energy used if a resonant circuit were not implemented.

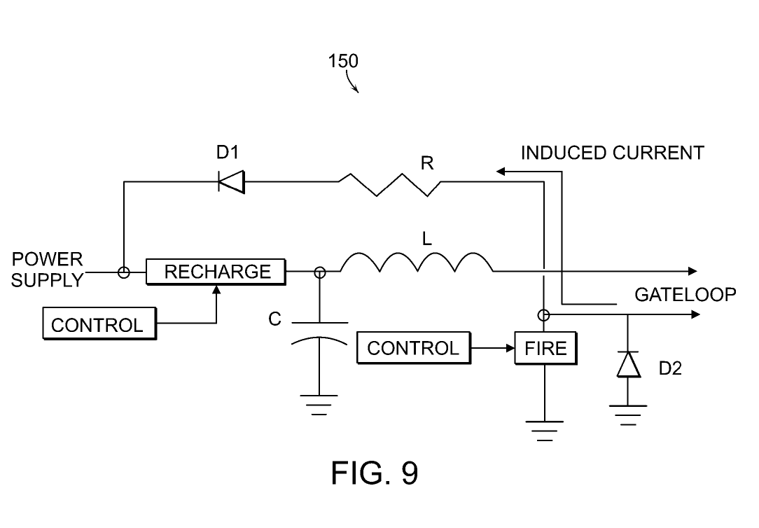

FIG. 9 shows a resonant gate drive 150 for the AC current-transformer coupled gate drive circuit 110. Two gate drive circuits are used to provide signals to a single shared isolation transformer (e.g., such as the isolation transformers 113, 117 or 121 shown in FIG. 7). More particularly, the output of the resonant gate drive 150 (GATE LOOP) is connected to an isolation transformer shown in FIG. 7. As such, when the two resonant gate drives 150 are connected to the isolation transformer, the two resonant gate drives 150 provide an alternating current to the isolation transformer.

The resonant gate drive circuit 150 includes a diode D2 that provides a return for the negative loop. Diode D2 recharges the resonant gate drive 150 and prevents the signal from the negative loop from being applied to the thyristor gate. Diode D2 is included in the resonant gate drive circuit 150 because the bridge rectifiers 114, 118, and 122 electrically connected to the output of the current transformers (shown in FIG. 7) do not provide a low impedance return for the negative loop.

With the loops from each gate drive circuit going through the same current transformer, each loop induces a current into the other loop. This induced current is dissipated in the other gate drive circuit reducing the output of the thyristor gate. In order to limit the effect of the reduction in output of the thyristor, resonant gate drive circuit 150 includes a high impedance resistor, R. Resistor R forms a high impedance return path for this induced current. The high impedance path minimizes the induced current and limits the over voltage on the transistor used in the FIRE circuit.

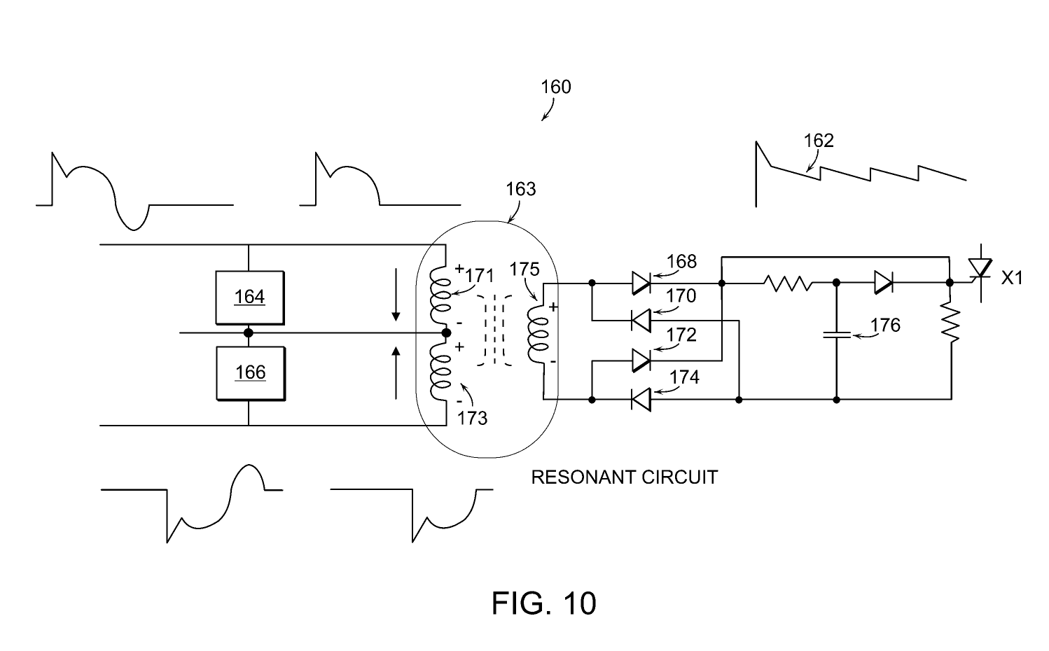

FIG. 10 shows an additional embodiment of a resonant circuit gate drive circuit 160 that provides a substantially continuous gate drive signal 162. Gate drive circuit 160 includes two resonant circuits 164 and 166 coupled to a single isolation transformer 163. Resonant circuit 164 is coupled to a first primary winding 171 isolation transformer 163 and resonant circuit 166 is coupled to a second primary winding 173 of the isolation transformer 163. The first and second primary windings 171 and 173 are electrically coupled to the secondary winding 175 of the isolation transformer 163.

The outputs of the two resonant circuits 164 and 166 are coupled to the isolation transformer 163 in opposite polarities. For example, the output of resonant circuit 164 is coupled in the same polarity orientation as transformer 163 while the output of resonant circuit 166 is coupled in the opposite polarity. As such, the output of resonant circuit 164 generates a positive gate drive current at isolation transformer 163 and the output of resonant circuit 166 generates a negative gate drive current at isolation transformer 163. A bridge rectifier that includes diodes 168, 170, 172, and 174 rectifies the positive and negative currents. Gate drive circuit 160 separates the negative recharge pulse circuit from the positive gate drive pulse circuit in the low portion of the recharge circuit. As such, only the positive gate drive pulse is coupled to the thyristor through the isolation transformer 163 allowing the use of only one isolation transformer 163 with the resonant circuit. At high voltage, the output of the rectifier is coupled to a capacitor 176 to provide a substantially continuous dc gate drive current 162. A bypass circuit is provided to transfer the fast front signal directly to the thyristor.

The resonant gate drive circuits 150 and 160 eliminate the residual magnetism in the transformer magnetic cores by providing an alternating-current resonant gate-drive. It is believed that using such an alternating-current resonant gate-drive increases the efficiency of the gate-drive and allows gate-drive operation with less input energy and/or the operation of a large number of series or parallel thyristors without increasing the energy of the gate-drive.

It is to be understood that the foregoing description is intended to illustrate and not to limit the scope of the invention, which is defined by the scope of the appended claims.

Other embodiments are within the scope of the following claims.

What is claimed is:

1. A resonant gate drive circuit, comprising:
an isolation transformer comprising a first primary winding; a second primary winding and a secondary winding;
a first resonant circuit coupled to the first primary winding, the first primary winding being disposed in a first polarity relative to the secondary winding;
a second resonant circuit coupled to the second primary winding, the second primary winding being disposed in a second polarity relative to the secondary winding, the second polarity being opposite of the first polarity; and
a rectifier circuit electrically connected to the isolation transformer.

2. The resonant gate drive circuit of claim 1, wherein:
the first resonant circuit is configured to generate a positive signal on the secondary winding of the isolation transformer;
the second resonant circuit is configured to generate a negative signal on the secondary winding of the isolation transformer; and
the rectifier circuit is configured to rectify the positive and negative signals.

3. The resonant gate drive circuit of claim 1, wherein the resonant gate drive circuit is configured to provide a substantially continuous gate drive signal to a thyristor.

4. The resonant gate drive circuit of claim 1, further comprising a capacitor electrically connected to an output of the rectifier circuit.

5. The resonant gate drive circuit of claim 4, further comprising a thyristor electrically connected to the capacitor.

6. The resonant gate drive circuit of claim 5, further comprising a resistor disposed in a current path between the capacitor and the thyristor.

7. A method for generating a gate drive signal, the method comprising:
receiving at an isolation transformer, alternate-polarity current pulses provided by a first resonant circuit and a second resonant circuit coupled to the isolation transformer in opposite polarities;
rectifying a signal generated by the isolation transformer; and
applying the rectified signal to a thyristor.

8. The method of claim 7, wherein the alternate-polarity current pulses comprise a first current pulse having a positive current value and a second current pulse having a negative current value.

9. The method of claim 7, wherein:
the isolation transformer comprises a first primary winding; a second primary winding and a secondary winding;
the first resonant circuit is coupled to the first primary winding, the first primary winding being disposed in a first polarity relative to the secondary winding;
the second resonant circuit is coupled to the second primary winding, the second primary winding being disposed in a second polarity relative to the secondary winding, the second polarity being opposite of the first polarity; and
receiving at the isolation transformer, alternate-polarity current pulses provided by the first resonant circuit and the second resonant circuit comprises receiving at the secondary winding a positive current from the first primary winding and receiving at the secondary winding a negative current from the second primary winding.

10. A circuit comprising:
a first resonant circuit; and
a second resonant circuit; and
a current transformer, wherein the first resonant circuit and the second resonant circuit are configured to provide alternate polarity current pulses through the current transformer for operation of a thyristor.

11. The circuit of claim 10, further comprising a rectifier circuit configured to rectify the signal from the transformer.

12. The circuit of claim 10, wherein the circuit is configured to separate a positive thyristor current pulse and a negative recharge current pulse.

13. An AC current-transformer coupled gate drive for simultaneous operation of a thyristor comprising:
a current transformer; and
one or more circuits to provide alternate polarity current pulses through the current transformer for operation of the thyristor.

14. The AC current-transformer coupled gate drive of claim 13, further comprising a rectifier circuit configured to rectify the signal from the current transformer prior to application of the signal to the thyristor.

15. The AC current-transformer coupled gate drive of claim 13, wherein the circuit is configured to separate a positive thyristor current pulse and a negative recharge current pulse.

16. The AC current-transformer coupled gate drive of claim 13 further comprising:
a diode electrically connected to the circuit, the diode being configured to provide a negative return loop for the circuit.

17. The AC current-transformer coupled gate drive of claim 13, wherein the one or more circuits comprise:
a first resonant circuit; and
a second resonant circuit.

18. The AC current-transformer coupled gate drive of claim 13, wherein:
the transformer comprises a first primary winding; a second primary winding and a secondary winding;
the first resonant circuit is coupled to the first primary winding, the first primary winding being disposed in a first polarity relative to the secondary winding;
the second resonant circuit is coupled to the second primary winding, the second primary winding being disposed in a second polarity relative to the secondary winding, the second polarity being opposite of the first polarity.
